(19) United States
(12) Patent Application Publication
(10) Pub. No.: US 2026/0026401 A1
(43) Pub. Date: Jan. 22, 2026

(54) SEMICONDUCTOR DEVICE, MEMORY DEVICE, AND METHOD FOR AUTOMATICALLY GENERATING CHIP IDENTIFIERS FOR SEMICONDUCTOR DIES IN STACKED STRUCTURE USING LOGIC GATES

(71) Applicant: NANYA TECHNOLOGY CORPORATION, NEW TAIPEI CITY (TW)

(72) Inventor: WU-DER YANG, NEW TAIPEI CITY (TW)

(21) Appl. No.: 18/816,143

(22) Filed: Aug. 27, 2024

Related U.S. Application Data
(62) Division of application No. 18/777,811, filed on Jul. 19, 2024.

(51) Int. Cl. H01L 25/18; H01L 23/00; H01L 25/065

(52) U.S. Cl. CPC H01L 25/18; H01L 24/08; H01L 25/0657; H01L 2224/08145; H01L 2225/06513; H01L 2225/06541; H01L 2924/1431

(57) ABSTRACT

A method for automatically generating chip identifier for semiconductor dies in a stacked structure is provided. The method includes the following steps: obtaining a first semiconductor die and a second semiconductor die, wherein the first semiconductor die and the second semiconductor die include a first identifier generation circuit and a second identifier generation circuit, respectively; forming a stacked structure by stacking the second semiconductor die on the first semiconductor die, wherein the first identifier generation circuit is electrically connected to the second identifier generation circuit; and generating a first chip identifier and a second chip identifier for the first semiconductor die and the second semiconductor die by the first identifier generation circuit and the second identifier generation circuit, respectively. The second chip identifier is generated using the first chip identifier and an auxiliary input signal.

### CROSS-REFERENCE TO RELATED APPLICATION

This application is a divisional application of U.S. Non-Provisional application Ser. No. 18/777,811 filed Jul. 19, 2024, which is incorporated herein by reference in its entirety.

### TECHNICAL FIELD

The present disclosure relates to electronic circuits, and more particularly, to a semiconductor device, a memory device, and a method for automatically generating chip identifiers for semiconductor dies in a stacked structure.

### DISCUSSION OF THE BACKGROUND

With the development of technology, memory devices can now have a much larger storage capacity by using a three-dimensional memory stack. Additionally, it is important for each memory chip within the stack to have a unique identifier. However, when manufacturing the memory stack, conflicts can occur if the chip identifiers are set before stacking, causing issues with different memory chips having the same identifier. Accordingly, there is a demand for a method for automatically generating chip identifiers for semiconductor dies in a stacked structure, a semiconductor device, and a memory device using the same to solve the aforementioned problem.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device, which includes a plurality of semiconductor dies arranged in a stacked structure. Each semiconductor die includes an identifier generation circuit electrically connected to the identifier generation circuits of other semiconductor dies. In response to a first semiconductor die not being a bottom semiconductor die within the stacked structure, a first identifier generation circuit of the first semiconductor die is configured to automatically generate a first chip identifier for the first semiconductor die based on an auxiliary input signal and a second chip identifier generated by a second identifier generation circuit of a second semiconductor die neighboring to and below the first semiconductor die.

Another aspect of the present disclosure provides a method for automatically generating chip identifier for semiconductor dies in a stacked structure. The method includes the following steps: obtaining a first semiconductor die and a second semiconductor die, wherein the first semiconductor die and the second semiconductor die comprise a first identifier generation circuit and a second identifier generation circuit, respectively; forming a stacked structure by stacking the second semiconductor die on the first semiconductor die, wherein the first identifier generation circuit is electrically connected to the second identifier generation circuit; and generating a first chip identifier and a second chip identifier for the first semiconductor die and the second semiconductor die by the first identifier generation circuit and the second identifier generation circuit, respectively, wherein the second chip identifier is generated using the first chip identifier and an auxiliary input signal.

Yet another aspect of the present disclosure provides a memory device, which includes a stacked structure having a first memory die and a second memory die. The first memory die is stacked on the second memory die. The first memory die and the second memory die include a first identifier generation circuit and a second identifier generation circuit, respectively. The second identifier generation circuit is configured to automatically generate a second chip identifier for the second memory die using a preset value and a first auxiliary input signal, and the first identifier generation circuit is configured to automatically generate a first chip identifier using the second chip identifier and a second auxiliary input signal.

The foregoing outlines rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

A more complete understanding of the present disclosure may be derived by referring to the detailed description and claims when considered in connection with the Figures, where like reference numbers refer to similar elements throughout the Figures, and:

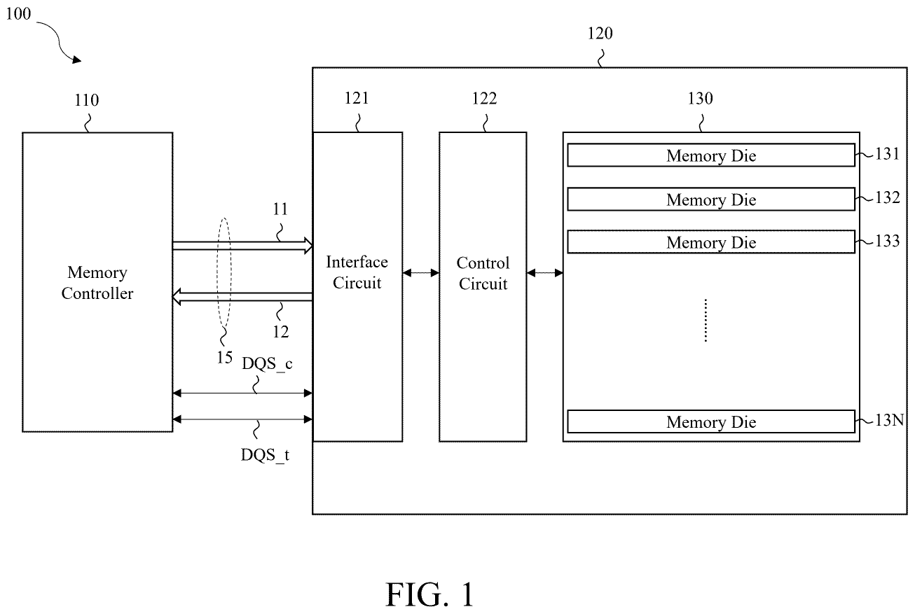

FIG. 1 is a block diagram of an electronic device 100 in accordance with some embodiments of the present disclosure.

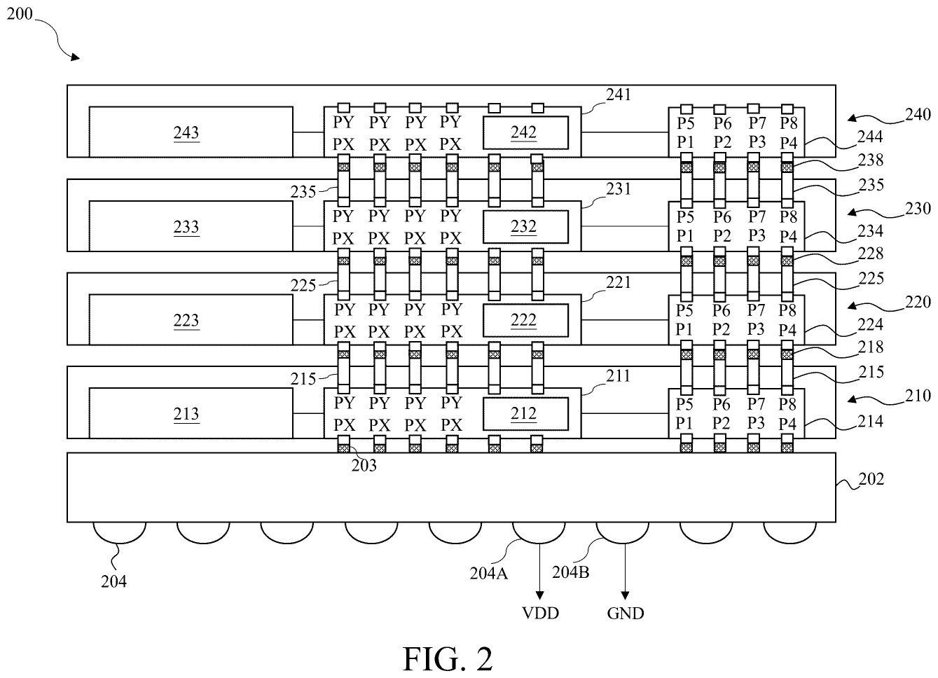

FIG. 2 is a diagram of a stacked structure in accordance with some embodiments of the present disclosure.

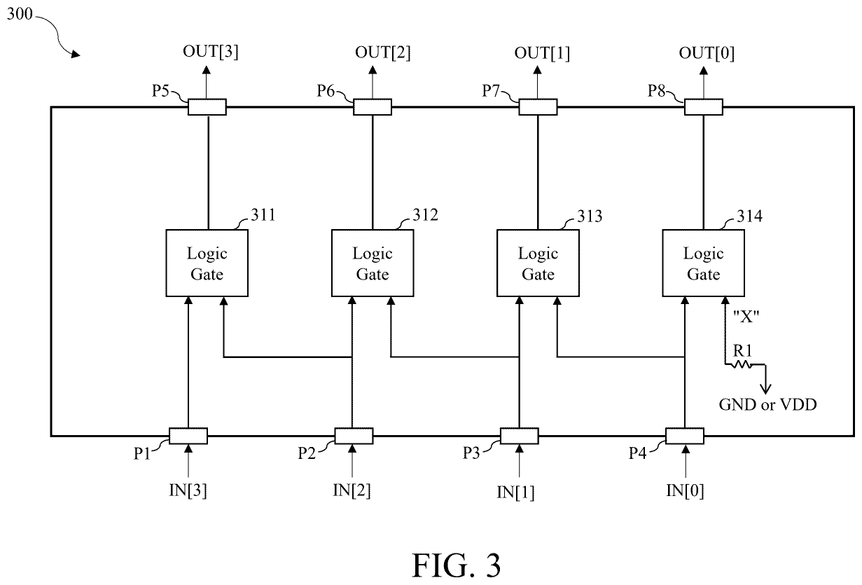

FIG. 3 is a schematic diagram of an identifier generation circuit in accordance with some embodiments of the present disclosure.

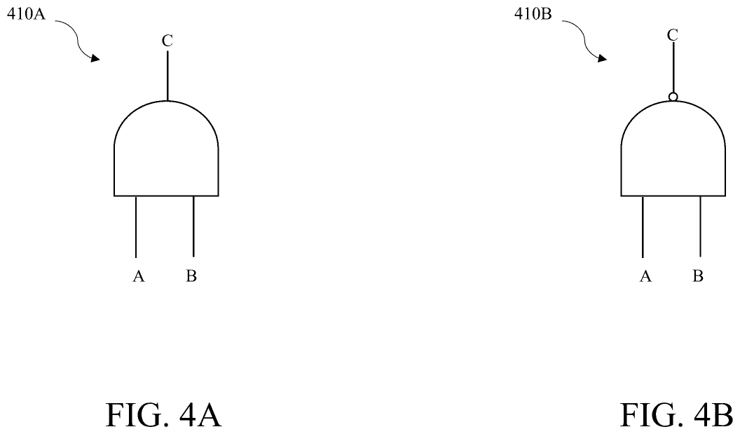

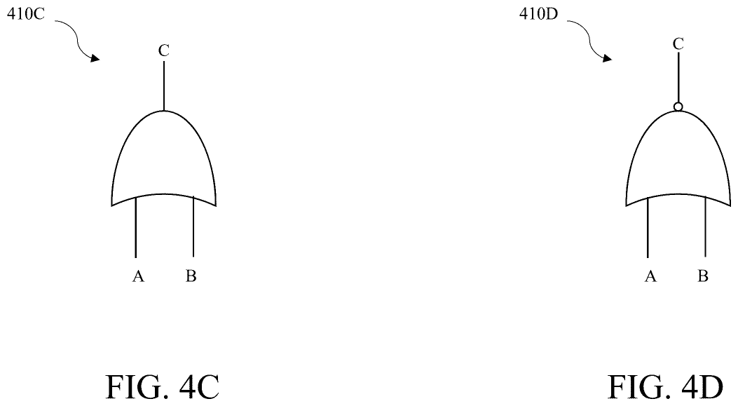

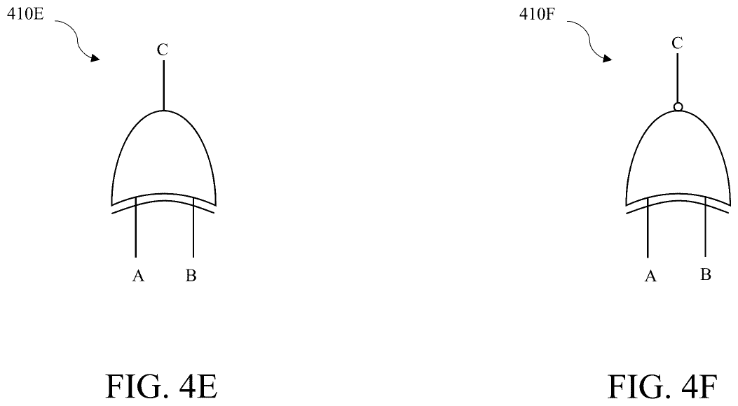

FIGS. 4A to 4F are diagrams of different logic gates used in the identifier generation circuit in FIG. 3.

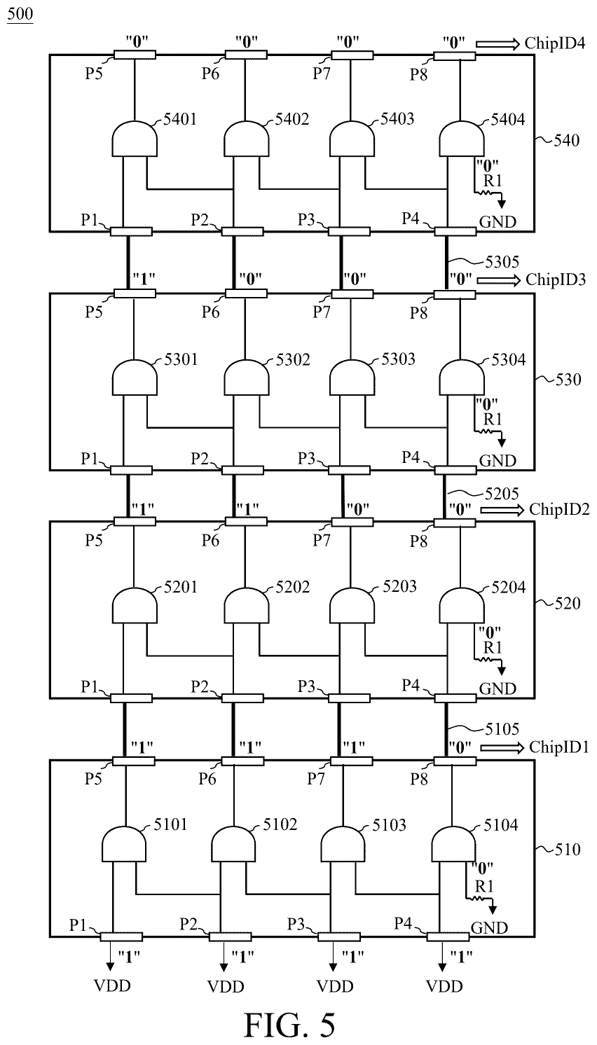

FIG. 5 is a diagram illustrating operations of a stacked structure of identifier generation circuits in accordance with some embodiments of the present disclosure.

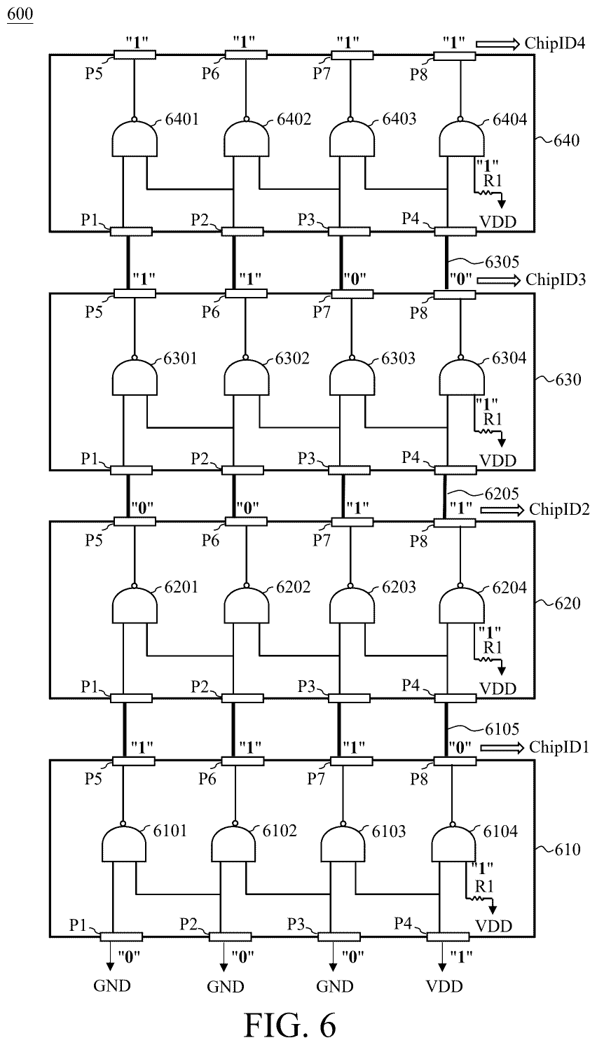

FIG. 6 is a diagram illustrating operations of a stacked structure of identifier generation circuits in accordance with some embodiments of the present disclosure.

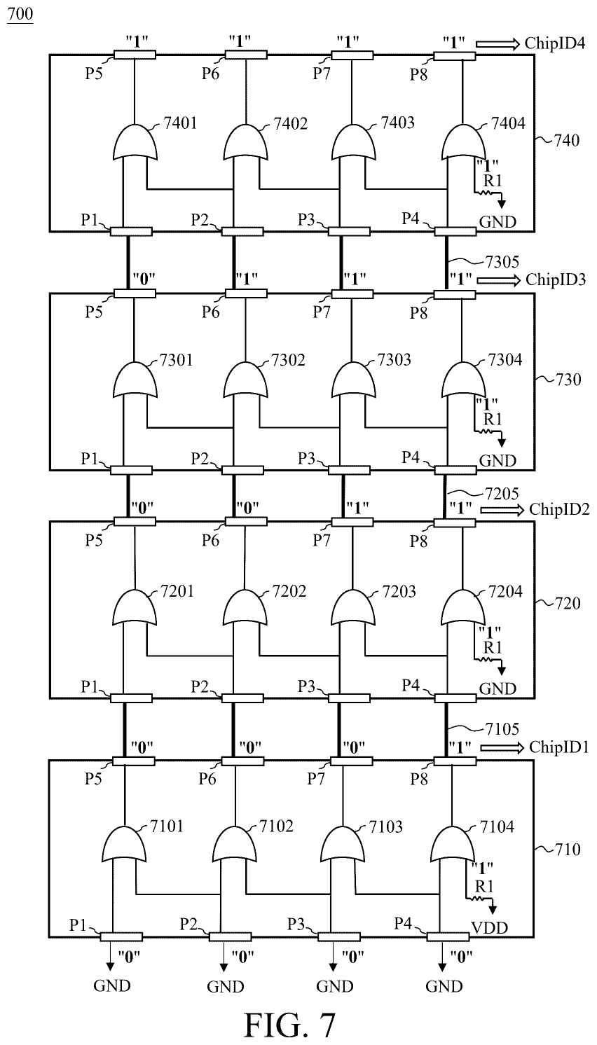

FIG. 7 is a diagram illustrating operations of a stacked structure of identifier generation circuits in accordance with some embodiments of the present disclosure.

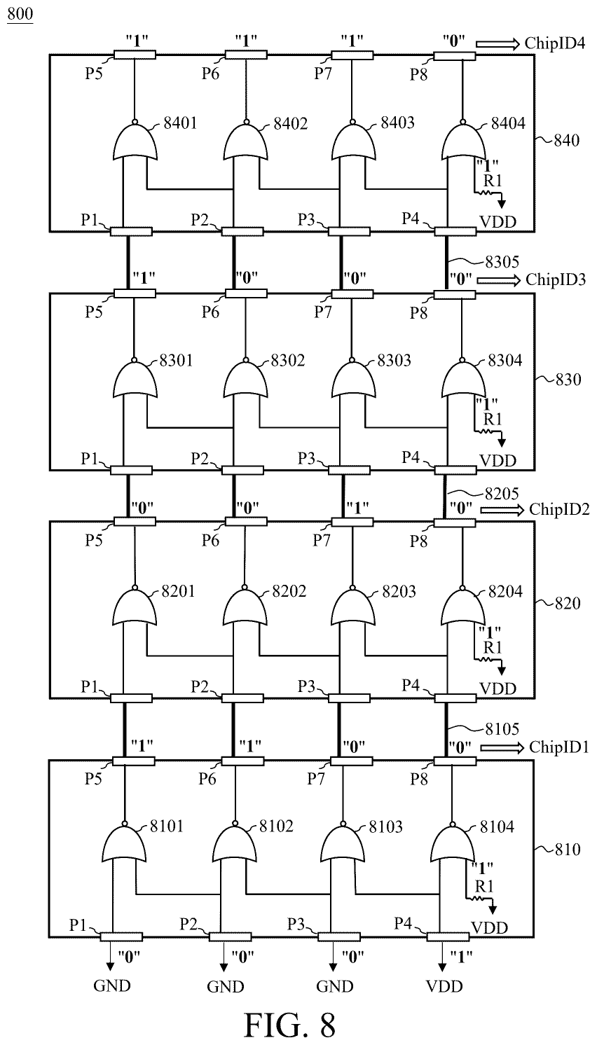

FIG. 8 is a diagram illustrating operations of a stacked structure of identifier generation circuits in accordance with some embodiments of the present disclosure.

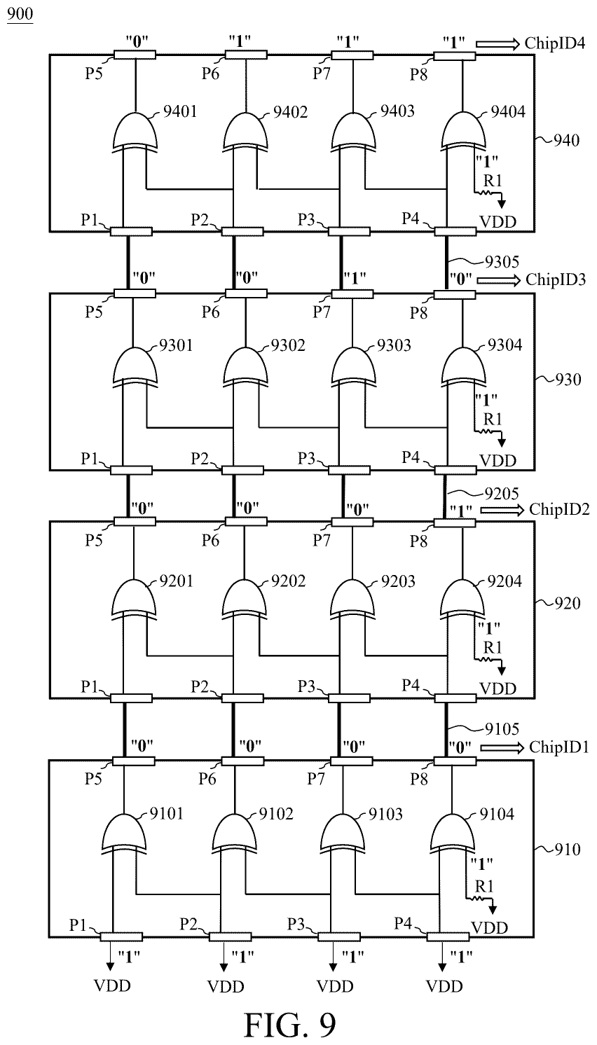

FIG. 9 is a diagram illustrating operations of a stacked structure of identifier generation circuits in accordance with some embodiments of the present disclosure.

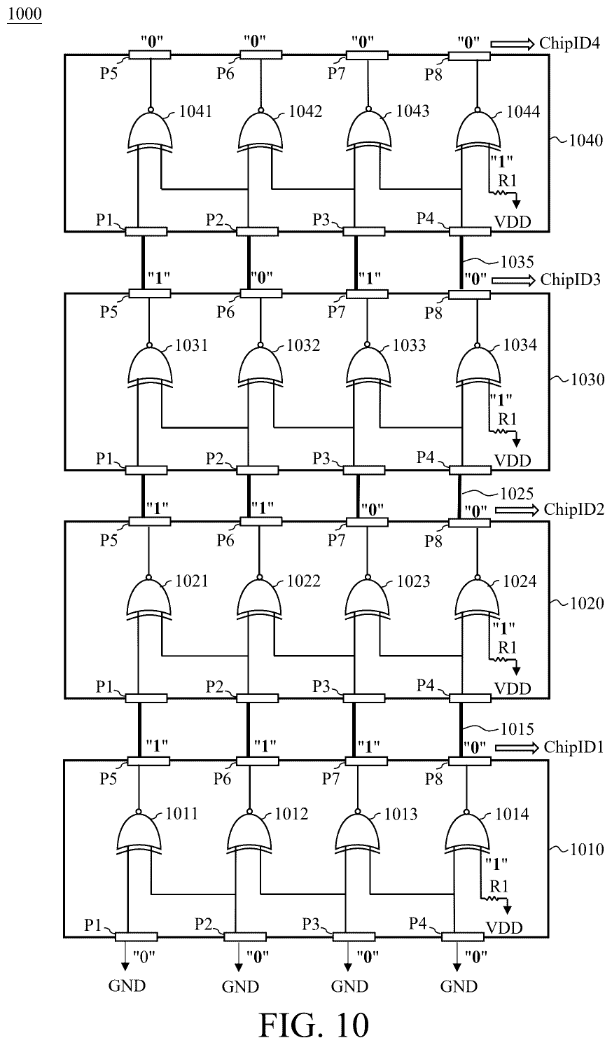

FIG. 10 is a diagram illustrating operations of a stacked structure of identifier generation circuits in accordance with some embodiments of the present disclosure.

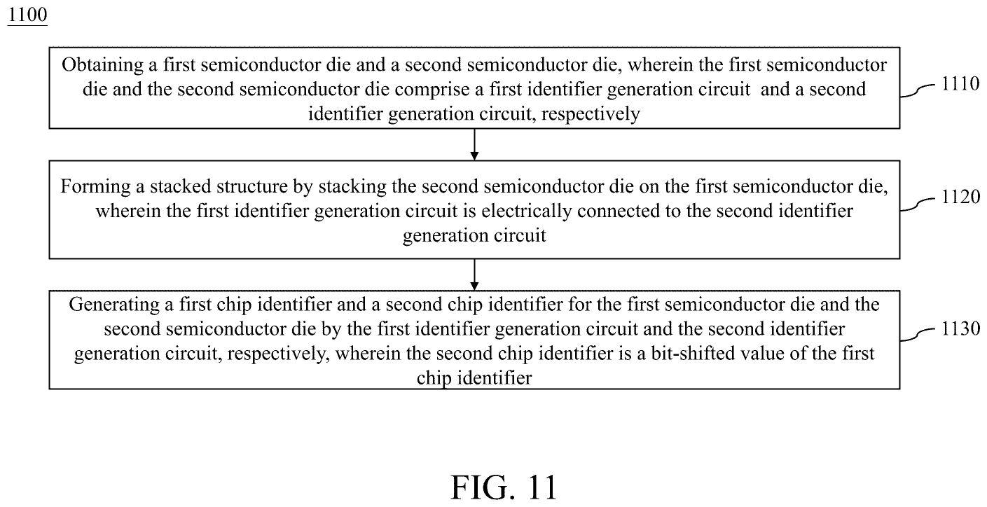

FIG. 11 is a flowchart of a method for automatically generating chip identifiers for semiconductor dies within a stacked structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

Reference throughout this specification to “one example” or “one embodiment” means that a particular feature, structure, or characteristic described in connection with the example is included in at least one example of the present invention. Thus, the appearances of the phrases “in one example” or “in one embodiment” in various places throughout this specification are not necessarily all referring to the same example. Furthermore, the particular features, structures, or characteristics may be combined in any suitable manner in one or more examples.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (for example, rotated 90° or at other orientations) and the spatially relative descriptors used herein interpreted accordingly. In addition, it will also be understood that when a layer is referred to as being “between” two layers, it can be the only layer between the two layers, or one or more intervening layers may also be present.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

It will be understood that when an element or layer is referred to as being “formed on,” another element or layer, it can be directly or indirectly formed on the other element or layer. That is, for example, intervening elements or layers may be present. In contrast, when an element or layer is referred to as being “directly formed on,” another element, there are no intervening elements or layers present. Other words used to describe the relationship between elements or layers should be interpreted in a like fashion (e.g., “between,” versus “directly between,” “adjacent,” versus “directly adjacent,” etc.).

FIG. 1 is a block diagram of an electronic device 100 in accordance with some embodiments of the present disclosure.

In some embodiments, the electronic device 100 may include a memory controller 110 and a memory device 120, as depicted in FIG. 1. The memory controller 110 may be implemented by a central processing unit (CPU), a microprocessor, a digital signal processor, a field-programmable gate arrays (FPGA), an application-specific integrated circuit (ASIC), or a radio-frequency integrated circuit (RFIC).

In some embodiments, the memory device 120 may be a dynamic random access memory (DRAM). In other embodiments, other types of memories can be used. For purposes of description, this disclosure may focus on double-date rate synchronous dynamic random access memory (DDR SDRAM) such as DDR5, but the scope of embodiments is not limited to any particular memory technology or standard.

In some embodiments, the memory device 120 may include an interface circuit 121, a control circuit 122, and a stacked structure 130, as depicted in FIG. 1. The interface circuit 121 may be configured to transmit and receive data signals 12 over bus 15, and to receive command control signals and address signals 11 and data strobe signals DQS_c and DQS_t from the memory controller 110 over bus 15. In other words, the interface circuit 121 may include TXm circuits (not explicitly shown) for the data signals 12, and RX circuits (not explicitly shown) for the command control signals and address signals 11, data signals 12, and data strobe signals DQS_c and DQS_t.

The stacked structure 130 may be a three-dimensional (3D) stacked memory architecture that includes a plurality of memory dies 131 to 13N. The memory dies 131 to 13N can be vertically stacked using through-silicon vias (TSVs) and microbump (ubump) interconnects, the details of which will be described later.

In some embodiments, the data strobe signal DQS_c may be a complementary signal of the data strobe signal DQS_t. For example, when the data strobe signal DQS_t is in the high logic state (e.g., 1), the data strobe signal DQS_c is in the low logic state (e.g., 0). When the data strobe signal DQS_t is in the low logic state (e.g., 0), the data strobe signal DQS_c is in the high logic state (e.g., 1).

In some embodiments, the control circuit 122 may perform a read operation or a write operation according to the command control signals 11 and the data strobe signals DQS_c and DQS_t. For example, during a write operation, the memory device 120 may receive a write command (e.g., including command control signal 11 and data signals 12) from the memory controller 110 over bus 15, and the control circuit 122 may then store the received data in the stacked structure 130. During a read operation, the memory device 120 may receive a read command signal (e.g., command control signal 11) from the memory controller 110 over bus 15, and the control circuit 122 may then access the data from various memory cells of the stacked structure 130, and transmit those bits of data (e.g., data signals 12) to the memory controller 110 over bus 15.

FIG. 2 is a diagram of a stacked structure in accordance with some embodiments of the present disclosure. Please refer to FIG. 1 and FIG. 2.

In some embodiments, the stacked structure 130 shown in FIG. 1 can be implemented using the stacked structure 200 shown in FIG. 2. For purposes of description, four semiconductor dies 210, 220, 230, and 240 are shown in FIG. 2. In some embodiments, the semiconductor dies 210, 220, 230, and 240 may correspond to the memory dies 131, 132, 133, and 134 in FIG. 1, respectively. The semiconductor die 210 may include logic circuitry 211, a memory cell array 213, and an identifier generation circuit 214. Similarly, the semiconductor die 220 may include logic circuitry 221, a memory cell array 223, and an identifier generation circuit 224, the semiconductor die 230 may include logic circuitry 231, a memory cell array 233, and an identifier generation circuit 234, and semiconductor die 240 may include logic circuitry 241, a memory cell array 243, and an identifier generation circuit 244.

In some embodiments, the semiconductor die 210 may include microbumps PX and PY formed on opposite sides of the logic circuitry 211, and microbumps P1 to P4 and P5 to P8 formed on opposite sides of the identifier generation circuit 214. For example, the microbumps PX and P1 to P4 may be formed on the front side of the semiconductor die 210. The semiconductor die 210 may be electrically connected to a package substrate 202 through the solder balls 203 and microbumps PX on the logic circuitry 211. Additionally, the package substrate 202 may be electrically connected to the memory controller 110 through the bumps 204 (e.g., copper bumps). Additionally, bumps 204A and 204B are electrically connected to the power supply voltage VDD and the ground voltage GND through a redistribution layer (not shown) within the package substrate 202, respectively. It should be noted that the semiconductor die 210 may include a plurality of through-silicon vias (TSV) 215, and each TSV 215 may correspond to one of the microbumps PY on the logic circuitry 211 and microbumps P5 to P8 on the identifier generation circuit 214.

Similarly, the semiconductor die 220 may include microbumps PX and PY formed on opposite sides of the logic circuitry 221, and microbumps P1 to P4 and P5 to P8 formed on opposite sides of the identifier generation circuit 224. For example, the microbumps PX and P1 to P4 may be formed on the front side of the semiconductor die 220. The semiconductor die 220 may be electrically connected to the semiconductor die 210 through the microbumps PX formed on the logic circuitry 221, the solder balls 218, TSVs 215, and microbumps PY and P5 to P8 of the semiconductor die 210, as depicted in FIG. 2. It should be noted that the semiconductor die 220 may include a plurality of through-silicon vias (TSV) 225, and each TSV 225 may correspond to one of the microbumps PY on the logic circuitry 221 and microbumps P5 to P8 on the identifier generation circuit 224.

Similarly, the semiconductor die 230 may include microbumps PX and PY formed on opposite sides of the logic circuitry 231, and microbumps P1 to P4 and P5 to P8 formed on opposite sides of the identifier generation circuit 234. For example, the microbumps PX and P1 to P4 may be formed on the front side of the semiconductor die 230. The semiconductor die 230 may be electrically connected to the semiconductor die 220 through the microbumps PX formed on the logic circuitry 231, the solder balls 228, TSVs 225, and microbumps PY and P5 to P8 of the semiconductor die 220, as depicted in FIG. 2.

Similarly, the semiconductor die 240 may include microbumps PX and PY formed on opposite sides of the logic circuitry 241, and microbumps P1 to P4 and P5 to P8 formed on opposite sides of the identifier generation circuit 244. For example, the microbumps PX and P1 to P4 may be formed on the front side of the semiconductor die 240. The semiconductor die 240 may be electrically connected to the semiconductor die 230 through the microbumps PX formed on the logic circuitry 241, the solder balls 238, TSVs 235, and microbumps PY and P5 to P8 of the semiconductor die 230, as depicted in FIG. 2.

In some embodiments, the logic circuitry 211, 221, 231, and 241 may be or include memory control logic for controlling data accessing of the memory cell array 213, 223, 233, 243, respectively. Additionally, the logic circuitry 211, 221, 231, and 241 may include decoder circuits 212, 222, 232, and 242 configured to coordinate the chip identifiers received from the identifier generation circuits 214, 224, 234, and 244 on the semiconductor dies 210, 220, 230, and 240, allowing the memory controller 110 to access, the command control signals and address signals 11, one of the memory cell arrays 213, 223, 233, and 243 disposed on the semiconductor dies 210, 220, 230, and 240, respectively.

In some embodiments, the memory cell arrays 213, 223, 233, and 243 on the semiconductor dies 210, 220, 230, and 240 may form a memory space. Each of the memory cell arrays 213, 223, 233, and 243 may be a portion of the memory space which corresponds to one or more most significant bits (MSB) of the address signal from the memory controller 110. In some embodiments, the memory controller 110 may access the memory cell arrays 213, 223, 233, and 243 disposed on the semiconductor dies 210, 220, 230, and 240 by setting the two most significant bits to 2′b00, 2′b01, 2′b10, and 2′b11, respectively.

For example, the decoder circuit 212 may receive the chip identifier of the semiconductor die 210 generated by the identifier generation circuit 214, and then transmit the received chip identifier to the decoder circuits 222, 232, and 242 disposed on other semiconductor dies, such as semiconductor dies 220, 230, and 240. Similarly, the decoder circuits 222, 232, and 242 may receive the chip identifier generated by the respective identifier generation circuits 224, 234, and 244 disposed their respective semiconductor dies 220, 230, and 240, and then transmit the received chip identifier to the decoders disposed on other semiconductor dies.

More specifically, the identifier generation circuits 214, 224, 234, and 244, which have the same circuit design, are electrically connected in series. Each of the identifier generation circuits 214, 224, 234, and 244 may generate a unique chip identifier (or die identifier) of the semiconductor die on which the respective one of identifier generation circuits 214, 224, 234, and 244 is disposed. Additionally, the chip identifier generated by each of the identifier generation circuits 214, 224, 234, and 244 may be based on the input signal of each identifier generation circuits 214, 224, 234, and 244.

In some embodiments, the semiconductor die 210 is the bottom semiconductor die or the first die among the stacked structure 200, and the identifier generation circuit 214 may generate a first 4-bit unique chip identifier (or die identifier) that represents the bottom die or the first die among the stacked structure 200. It should be noted that the microbumps P1 to P4 disposed on the identifier generation circuit 214 of the semiconductor die 210 may be electrically connected to the bumps 204A (e.g., connected to the power supply voltage VDD) or 204B (e.g., connected to the ground voltage GND) via respective solder balls 203 on the package substrate 202, and the identifier generation circuit 214 may automatically generate the 4-bit chip identifier by perform the corresponding logical operation between two input signals of each logic gate (e.g., AND, NAND, OR, NOR, XOR, and XNOR gates) used in identifier generation circuit 214. For example, the 4-bit chip identifier can be encoded in any encoding method known in the art.

In some embodiments, the semiconductor die 220 is the second die among the stacked structure 200, and the identifier generation circuit 224 may generate a second 4-bit unique chip identifier (or die identifier) that represents the second die among the stacked structure 200. For example, the chip identifier generated by the identifier generation circuit 214 may be used as the input signal of the identifier generation circuit 224, and the identifier generation circuit 224 may perform the corresponding logical operation on two input signals of each logic gate therein to obtain the output chip identifier for the semiconductor die 220.

In some embodiments, the semiconductor die 230 is the third die among the stacked structure 200, and the identifier generation circuit 234 may generate a third 4-bit unique chip identifier (or die identifier) that represents the third die among the stacked structure 200. For example, the chip identifier generated by the identifier generation circuit 224 may be used as the input signal of the identifier generation circuit 234, and the identifier generation circuit 234 may perform the corresponding logical operation on two input signals of each logic gate therein to obtain the output chip identifier for the semiconductor die 230.

In some embodiments, the semiconductor die 240 is the fourth die or the topmost die among the stacked structure 200, and the identifier generation circuit 244 may generate a fourth 4-bit unique chip identifier (or die identifier) that represents the fourth die among the stacked structure 200. For example, the chip identifier generated by the identifier generation circuit 234 may be used as the input signal of the identifier generation circuit 244, and the identifier generation circuit 244 may perform the corresponding logical operation on two input signals of each logic gate therein to obtain the output chip identifier for the semiconductor die 240.

It should be noted that the semiconductor dies 210, 220, 230, and 240 may have substantially the same circuit design. No matter whether the order of the semiconductor dies 210, 220, 230, and 240 within the stacked structure 200 is changed, the identifier generation circuits 214, 224, 234, and 244 are still capable of generating correct and unique chip identifiers for the semiconductor dies 210, 220, 230, and 240 with respect to their locations within the stacked structure 200.

FIG. 3 is a schematic diagram of an identifier generation circuit in accordance with some embodiments of the present disclosure.

In some embodiments, each of the identifier generation circuits 214, 224, 234, and 244 shown in FIG. 2 may be implemented using the identifier generation circuit 300 shown in FIG. 3. The identifier generation circuit 300 may include input ports P1 to P4, output ports P5 to P8, and a plurality of logic gates 311 to 314. Each logic gate 311 to 314 may be a 2-input logic gate of the same type (e.g., AND, NAND, OR, NOR, XOR, or XNOR). For purposes of description, the left input terminal and the right input terminal of each logic gate 311 to 314 can be regarded as a first input terminal and a second input terminal.

In some embodiments, the first input terminal of the logic gate 311 receives the input signal IN[3] from the input port P1 of the identifier generation circuit 300, and the second input terminal receives the input signal IN[2] from the input port P2 of the identifier generation circuit 300. The logic gate 311 generates an output signal OUT [3] at the output port P5 of the identifier generation circuit 300 based on the received input signals IN[3] and IN[2]. The input signals IN[3] and IN[2] can be either the power supply voltage VDD or the ground voltage GND that represent the high logic state (e.g., “1”) or the low logic state (e.g., “0”), respectively.

Similarly, the first input terminal and the second input terminal of the logic gate 312 receive the input signals IN[2] and IN[1] from the input ports P2 and P3 of the identifier generation circuit 300, respectively. The logic gate 312 generates an output signal OUT [2] at the output port P6 of the identifier generation circuit 300 based on the received input signals IN[2] and IN[1]. The input signals IN[2] and IN[1] can be either the power supply voltage VDD or the ground voltage GND that represent the high logic state (e.g., “1”) or the low logic state (e.g., “0”), respectively.

Additionally, the first input terminal and the second input terminal of the logic gate 313 receive the input signals IN[1] and IN[0] from the input ports P3 and P4 of the identifier generation circuit 300, respectively. The logic gate 313 generates an output signal OUT [1] at the output port P7 of the identifier generation circuit 300 based on the received input signals IN[1] and IN[0]. The input signals IN[2] and IN[1] can be the power supply voltage VDD or the ground voltage GND that represent the high logic state (e.g., “1”) or the low logic state (e.g., “0”), respectively.

Furthermore, the first input terminal of the logic gate 314 receives the input signals IN[0] from the input port P4 of the identifier generation circuit 300, while the second input terminal of the logic gate 314 receives a source voltage (e.g., GND or VDD) through a resistor R1, respectively. For example, when the second input terminal of the logic gate 314 is connected to the power supply voltage VDD and the ground voltage GND, the auxiliary input signal X is in the high logic state (e.g., “1”) and the low logic state (e.g., “0”), respectively. It should be noted that the source voltage (e.g., GND or VDD) may depend on the type of logic gates 311 to 314 being used. The details thereof are described as follows.

FIGS. 4A to 4D are diagrams of different logic gates used in the identifier generation circuit in FIG. 3.

In some embodiments, each of the logic gates 311 to 314 in FIG. 3 can be implemented using the logic gate 410A shown in FIG. 4A. For example, the logic gate 410A may be a two-input AND gate that receives input signals A and B. Table 1 shows the truth table of the logic gate 410A.

TABLE 1

| A | B | C |
|---|---|---|
| 0 | 0 | 0 |
| 0 | 1 | 0 |
| 1 | 0 | 0 |
| 1 | 1 | 1 |

In other words, the logic gate 410A may perform an AND operation on the input signals A and B to generate an output signal C. For example, when any of the input signals A and B is in the low logic state (e.g., “0”), the output signal C is in the low logic state (e.g., “0”). When both the input signals A and B are in the high logic state (e.g., “1”), the output C is in the high logic state (e.g., “1”).

FIG. 4B shows another configuration of the logic gate in FIG. 3. In some embodiments, each of the logic gates 311 to 314 in FIG. 3 can be implemented using the logic gate 410B shown in FIG. 4B. For example, the logic gate 410B may be a two-input NAND gate that receives input signals A and B. Table 2 shows the truth table of the logic gate 410B.

TABLE 2

| A | B | C |
|---|---|---|
| 0 | 0 | 1 |
| 0 | 1 | 1 |
| 1 | 0 | 1 |
| 1 | 1 | 0 |

In other words, the logic gate 410B may perform an NAND operation on the input signals A and B to generate an output signal C. For example, when any of the input signals A and B is in the low logic state (e.g., “0”), the output signal C is in the high logic state (e.g., “1”). When both the input signals A and B are in the high logic state (e.g., “1”), the output C is in the low logic state (e.g., “0”).

FIG. 4C shows yet another configuration of the logic gate in FIG. 3. In some embodiments, each of the logic gates 311 to 314 in FIG. 3 can be implemented using the logic gate 410C shown in FIG. 4C. For example, the logic gate 410C may be a two-input OR gate that receives input signals A and B. Table 3 shows the truth table of the logic gate 410C.

TABLE 3

| A | B | C |
|---|---|---|
| 0 | 0 | 0 |
| 0 | 1 | 1 |
| 1 | 0 | 1 |
| 1 | 1 | 1 |

In other words, the logic gate 410C may perform an OR operation on the input signals A and B to generate an output signal C. For example, when any of the input signals A and B is in the high logic state (e.g., “1”), the output signal C is in the high logic state (e.g., “1”). When both the input signals A and B are in the low logic state (e.g., “0”), the output C is in the high logic state (e.g., “0”).

FIG. 4D shows yet another configuration of the logic gate in FIG. 3. In some embodiments, each of the logic gates 311 to 314 in FIG. 3 can be implemented using the logic gate 410D shown in FIG. 4D. For example, the logic gate 410D may be a two-input NOR gate that receives input signals A and B. Table 4 shows the truth table of the logic gate 410D.

TABLE 4

| A | B | C |
|---|---|---|
| 0 | 0 | 1 |
| 0 | 1 | 0 |
| 1 | 0 | 0 |
| 1 | 1 | 0 |

In other words, the logic gate 410D may perform an NOR operation on the input signals A and B to generate an output signal C. For example, when any of the input signals A and B is in the high logic state (e.g., “1”), the output signal C is in the low logic state (e.g., “0”). When both the input signals A and B are in the low logic state (e.g., “1”), the output C is in the high logic state (e.g., “1”).

FIG. 4E shows yet another configuration of the logic gate in FIG. 3. In some embodiments, each of the logic gates 311 to 314 in FIG. 3 can be implemented using the logic gate 410E shown in FIG. 4E. For example, the logic gate 410E may be a two-input XOR gate that receives input signals A and B. Table 5 shows the truth table of the logic gate 410E.

TABLE 5

| A | B | C |
|---|---|---|
| 0 | 0 | 0 |
| 0 | 1 | 1 |
| 1 | 0 | 1 |
| 1 | 1 | 0 |

In other words, the logic gate 410E may perform an XOR operation on the input signals A and B to generate an output signal C. For example, when the input signals A and B have different logic states (e.g., A=1, B=0, or A=0, B=1), the output signal C is in the high logic state (e.g., “1”). When both the input signals A and B have the same logic states (e.g., A=B=1, or A=B=0), the output C is in the low logic state (e.g., “0”).

FIG. 4F shows yet another configuration of the logic gate in FIG. 3. In some embodiments, each of the logic gates 311 to 314 in FIG. 3 can be implemented using the logic gate 410F shown in FIG. 4F. For example, the logic gate 410F may be a two-input XNOR gate that receives input signals A and B. Table 6 shows the truth table of the logic gate 410F.

TABLE 4

| A | B | C |
|---|---|---|
| 0 | 0 | 1 |
| 0 | 1 | 0 |
| 1 | 0 | 0 |
| 1 | 1 | 1 |

In other words, the logic gate 410F may perform an XNOR operation on the input signals A and B to generate an output signal C. For example, when the input signals A and B have different logic states (e.g., A=1 and B=0, or A=0 and B=1), the output signal C is in the low logic state (e.g., “0”). When both the input signals A and B have the same logic states (e.g., A=B=1, or A=B=0), the output C is in the high logic state (e.g., “1”).

It should be noted that the logic gates 410A to 410F shown in FIGS. 4A to 4F are for purposes of description, and the logic gates 311 to 314 shown in FIG. 3 can be implemented using any other two-input logic gate (e.g., A and NOT B, B and NOT A, A or NOT B, B or NOT A) in addition to the logic gates 410A to 410F.

FIG. 5 is a diagram illustrating operations of a stacked structure of identifier generation circuits in accordance with some embodiments of the present disclosure.

In some embodiments, the identifier generation circuits 510, 520, 530, and 540 within stacked structure 500 shown in FIG. 5 may correspond to the identifier generation circuits 214, 224, 234, and 244 disposed on semiconductor dies 210, 220, 230, and 240 shown in FIG. 2, respectively. In other words, the identifier generation circuits 510, 520, 530, and 540 are disposed on different semiconductor dies (not explicitly shown in FIG. 5). Additionally, the schematic diagrams of identifier generation circuit 510, 520, 530, and 540 with their respective input and output signals are shown in FIG. 5.

In some embodiments, the identifier generation circuit 510 may be disposed on a bottom semiconductor die among stacked structure 500, and the input ports P1 to P4 of the identifier generation circuit 510 are connected to the power supply voltage VDD, indicating that the input signal IN[3:0]=4′b1111 (e.g., 0xF in hexadecimal). Additionally, since the second input terminal of the logic state 5104 is connected to the ground voltage GND through the resistor R1, the auxiliary input signal of the logic state 5104 is in the low logic state (e.g., “0”). Each of the logic gates 5101 to 5104 may perform an AND operation on the corresponding bit and its adjacent lower bit of the input signal IN. For example, the logic gate 5101 perform the AND operation on the corresponding bit IN[3] received from the corresponding input port P1 and its adjacent lower bit IN[2] received from the adjacent input port P2. The operation for the logic gates 5102 to 5104 can be derived in a similar manner.

It should be noted that the auxiliary input signal serves as the adjacent lower bit for the logic state 5104. Accordingly, based on the truth table shown in Table 1, the output signals of the logic gates 5101 to 5104 are “1”, “1”, “1”, and “0”, that are transmitted to the output ports P5, P6, P7, and P8 of the identifier generation circuit 510, respectively. Accordingly, the output signals “1”, “1”, “1”, and “0” generated by the logic gates 5101 to 5104 at the output ports P5 to P8 of the identifier generation circuit 510 will serve as both the chip identifier ChipID1 (e.g., 4′b1110 or 0xE in hexadecimal) and the input signals at the input ports P1 to P4 of the identifier generation circuit 520.

Since the identifier generation circuit 520 is disposed on the second semiconductor die among stacked structure 500, the input ports P1 to P4 of the identifier generation circuit 520 are connected the output ports P5 to P8 of the identifier generation circuit 510 through TSVs 5105, respectively. Accordingly, the input signals of the first terminals of the logic gates 5201 to 5204 of the identifier generation circuit 520 will follow the input signals “1”, “1”, “1”, and “0” received at the input ports P1 to P4 of the identifier generation circuit 520, respectively. Accordingly, the output signals “1”, “1”, “0”, and “0” generated by the logic gates 5201 to 5204 at the output ports P5 to P8 of the identifier generation circuit 520 will serve as both the chip identifier ChipID2 (e.g., 4′b1100 or 0xC in hexadecimal) and the input signals at the input ports P1 to P4 of the identifier generation circuit 530.

Similarly, since the identifier generation circuit 530 disposed on the third semiconductor die among stacked structure 500, the input ports P1 to P4 of the identifier generation circuit 530 are connected the output ports P5 to P8 of the identifier generation circuit 520 through TSVs 5205, respectively. Accordingly, the input signals of the first terminals of the logic gates 5301 to 5304 of the identifier generation circuit 530 will follow the input signals “1”, “1”, “0”, and “0” received at the input port P1 to P4 of the identifier generation circuit 530, respectively. Accordingly, the output signals “1”, “0”, “0”, and “0” generated by the logic gates 5301 to 5304 at the output ports P5 to P8 of the identifier generation circuit 530 will serve as both the chip identifier ChipID3 (e.g., 4′b1000, or 0×8 in hexadecimal) and the input signals at the input ports P1 to P4 of the identifier generation circuit 540.

Similarly, since the identifier generation circuit 540 is disposed on the fourth semiconductor die (or topmost semiconductor die) among stacked structure 500, the input ports P1 to P4 of the identifier generation circuit 540 are connected the output ports P5 to P8 of the identifier generation circuit 530 through TSVs 5305, respectively. Accordingly, the input signals of the first terminals of the logic gates 5401 to 5404 of the identifier generation circuit 540 will follow the input signals “1”, “0”, “0”, and “0” received at the input port P1 to P4 of the identifier generation circuit 540, respectively. Accordingly, the output signals “0”, “0”, “0”, and “0” generated by the logic gates 5401 to 5404 at the output ports P5 to P8 of the identifier generation circuit 540 will serve as the chip identifier ChipID4 (e.g., 4′b0000 or 0x0 in hexadecimal).

It should be noted that the output signals of the identifier generation circuits 510, 520, 530, and 540 may be transmitted to the corresponding decoder circuits, such as the decoder circuits 212, 222, 232, and 242 shown in FIG. 2, allowing the logic circuitry disposed on different semiconductor dies to control the respective memory cell array (e.g., memory cell array 213, 223, 233, and 243 shown in FIG. 2) using the output signals from the identifier generation circuits 510, 520, 530, and 540.

FIG. 6 is a diagram illustrating operations of a stacked structure of identifier generation circuits in accordance with some embodiments of the present disclosure.

In some embodiments, the identifier generation circuits 610, 620, 630, and 640 within stacked structure 600 shown in FIG. 6 may correspond to the identifier generation circuits 214, 224, 234, and 244 disposed on semiconductor dies 210, 220, 230, and 240 shown in FIG. 2, respectively. In other words, the identifier generation circuits 610, 620, 630, and 640 are disposed on different semiconductor dies (not explicitly shown in FIG. 6). Additionally, the schematic diagrams of identifier generation circuit 610, 620, 630, and 640 with their respective input and output signals are shown in FIG. 6.

In some embodiments, the identifier generation circuit 610 may be disposed on a bottom semiconductor die among stacked structure 600. The input ports P1 to P3 of the identifier generation circuit 610 are connected to the ground voltage GND, while the input port P4 of the identifier generation circuit 610 is connected to the power supply voltage VDD, indicating that the input signal IN[3:0]=4′b0001 (e.g. 0x1 in hexadecimal). Additionally, since the second input terminal of the logic state 6104 is connected to the power supply voltage VDD through the resistor R1, the auxiliary input signal of the logic state 6104 is in the high logic state (e.g., “1”). Each of the logic gates 6101 to 6104 may perform a NAND operation on the corresponding bit and its adjacent lower bit of the input signal IN. For example, the logic gate 6101 perform the NAND operation on the corresponding bit IN[3] received from the corresponding input port P1 and its adjacent lower bit IN[2] received from the adjacent input port P2. The operation for the logic gates 6102 to 6104 can be derived in a similar manner.

It should be noted that the auxiliary input signal serves as the adjacent lower bit for the logic state 6104. Accordingly, based on the truth table shown in Table 2, the output signals of the logic gates 6101 to 6104 are “1”, “1”, “1”, and “0”, that are transmitted to the output ports P5, P6, P7, and P8 of the identifier generation circuit 610, respectively. Accordingly, the output signals “1”, “1”, “1”, and “0” generated by the logic gates 6101 to 6104 at the output ports P5 to P8 of the identifier generation circuit 610 will serve as both the chip identifier ChipID1 (e.g., 4′b1110, or 0xE in hexadecimal) and the input signals at the input ports P1 to P4 of the identifier generation circuit 620.

Since the identifier generation circuit 620 is disposed on the second semiconductor die among stacked structure 600, the input ports P1 to P4 of the identifier generation circuit 620 are connected the output ports P5 to P8 of the identifier generation circuit 610 through TSVs 6105, respectively. Accordingly, the input signals of the first terminals of the logic gates 6201 to 6204 of the identifier generation circuit 620 will follow the input signals “1”, “1”, “1”, and “0” received at the input ports P1 to P4 of the identifier generation circuit 620, respectively. Accordingly, the output signals “0”, “0”, “1”, and “1” generated by the logic gates 6201 to 6204 at the output ports P5 to P8 of the identifier generation circuit 620 will serve as both the chip identifier ChipID2 (e.g., 4′b0011 or 0x3 in hexadecimal) and the input signals at the input ports P1 to P4 of the identifier generation circuit 630.

Similarly, since the identifier generation circuit 630 disposed on the third semiconductor die among stacked structure 600, the input ports P1 to P4 of the identifier generation circuit 630 are connected the output ports P5 to P8 of the identifier generation circuit 620 through TSVs 6205, respectively. Accordingly, the input signals of the first terminals of the logic gates 6301 to 6304 of the identifier generation circuit 630 will follow the input signals “0”, “0”, “1”, and “1” received at the input port P1 to P4 of the identifier generation circuit 630, respectively. Accordingly, the output signals “1”, “1”, “0”, and “0” generated by the logic gates 6301 to 6304 at the output ports P5 to P8 of the identifier generation circuit 630 will serve as both the chip identifier ChipID3 (e.g., 4′b1100 or 0xC in hexadecimal) and the input signals at the input ports P1 to P4 of the identifier generation circuit 640.

Similarly, since the identifier generation circuit 640 is disposed on the fourth semiconductor die (or topmost semiconductor die) among stacked structure 600, the input ports P1 to P4 of the identifier generation circuit 640 are connected the output ports P5 to P8 of the identifier generation circuit 630 through TSVs 6305, respectively. Accordingly, the input signals of the first terminals of the logic gates 6401 to 6404 of the identifier generation circuit 640 will follow the input signals “1”, “1”, “0”, and “0” received at the input port P1 to P4 of the identifier generation circuit 640, respectively. Accordingly, the output signals “0”, “1”, “1”, and “1” generated by the logic gates 6401 to 6404 at the output ports P5 to P8 of the identifier generation circuit 640 will serve as the chip identifier ChipID4 (e.g., 4′b0111 or 0x7 in hexadecimal).

It should be noted that the output signals of the identifier generation circuits 610, 620, 630, and 640 may be transmitted to the corresponding decoder circuits, such as the decoder circuits 212, 222, 232, and 242 shown in FIG. 2, allowing the logic circuitry disposed on different semiconductor dies to control the respective memory cell array (e.g., memory cell array 213, 223, 233, and 243 shown in FIG. 2) using the output signals from the identifier generation circuits 610, 620, 630, and 640.

FIG. 7 is a diagram illustrating operations of a stacked structure of identifier generation circuits in accordance with some embodiments of the present disclosure.

In some embodiments, the identifier generation circuits 710, 720, 730, and 740 within stacked structure 700 shown in FIG. 7 may correspond to the identifier generation circuits 214, 224, 234, and 244 disposed on semiconductor dies 210, 220, 230, and 240 shown in FIG. 2, respectively. In other words, the identifier generation circuits 710, 720, 730, and 740 are disposed on different semiconductor dies (not explicitly shown in FIG. 7). Additionally, the schematic diagrams of identifier generation circuit 710, 720, 730, and 740 with their respective input and output signals are shown in FIG. 7.

In some embodiments, the identifier generation circuit 710 may be disposed on a bottom semiconductor die among stacked structure 700. The input ports P1 to P4 of the identifier generation circuit 710 are connected to the ground voltage GND, indicating that the input signal IN[3:0]=4′b0000 (e.g., 0x0 in hexadecimal). Additionally, since the second input terminal of the logic state 7104 is connected to the power supply voltage VDD through the resistor R1, the auxiliary input signal of the logic state 7104 is in the high logic state (e.g., “1”). Each of the logic gates 7101 to 7104 may perform an OR operation on the corresponding bit and its adjacent lower bit of the input signal IN. For example, the logic gate 7101 perform the OR operation on the corresponding bit IN[3] received from the corresponding input port P1 and its adjacent lower bit IN[2] received from the adjacent input port P2. The operation for the logic gates 7102 to 7104 can be derived in a similar manner.

It should be noted that the auxiliary input signal serves as the adjacent lower bit for the logic state 7104. Accordingly, based on the truth table shown in Table 3, the output signals of the logic gates 7101 to 7104 are “0”, “0”, “0”, and “1”, that are transmitted to the output ports P5, P6, P7, and P8 of the identifier generation circuit 710, respectively. Accordingly, the output signals “0”, “0”, “0”, and “1” generated by the logic gates 7101 to 7104 at the output ports P5 to P8 of the identifier generation circuit 710 will serve as both the chip identifier ChipID1 (e.g., 4′b0001 or 0x1 in hexadecimal) and the input signals at the input ports P1 to P4 of the identifier generation circuit 720.

Since the identifier generation circuit 720 is disposed on the second semiconductor die among stacked structure 700, the input ports P1 to P4 of the identifier generation circuit 720 are connected the output ports P5 to P8 of the identifier generation circuit 710 through TSVs 7105, respectively. Accordingly, the input signals of the first terminals of the logic gates 7201 to 7204 of the identifier generation circuit 720 will follow the input signals “0”, “0”, “0”, and “1” received at the input ports P1 to P4 of the identifier generation circuit 720, respectively. Accordingly, the output signals “0”, “0”, “1”, and “1” generated by the logic gates 7201 to 7204 at the output ports P5 to P8 of the identifier generation circuit 720 will serve as both the chip identifier ChipID2 (e.g., 4′b0011 or 0x3 in hexadecimal) and the input signals at the input ports P1 to P4 of the identifier generation circuit 730.

Similarly, since the identifier generation circuit 730 disposed on the third semiconductor die among stacked structure 700, the input ports P1 to P4 of the identifier generation circuit 730 are connected the output ports P5 to P8 of the identifier generation circuit 720 through TSVs 7205, respectively. Accordingly, the input signals of the first terminals of the logic gates 7301 to 7304 of the identifier generation circuit 730 will follow the input signals “0”, “0”, “1”, and “1” received at the input port P1 to P4 of the identifier generation circuit 730, respectively. Accordingly, the output signals “0”, “1”, “1”, and “1” generated by the logic gates 7301 to 7304 at the output ports P5 to P8 of the identifier generation circuit 730 will serve as both the chip identifier ChipID3 (e.g., 4′b0111 or 0x7 in hexadecimal) and the input signals at the input ports P1 to P4 of the identifier generation circuit 740.

Similarly, since the identifier generation circuit 740 is disposed on the fourth semiconductor die (or topmost semiconductor die) among stacked structure 700, the input ports P1 to P4 of the identifier generation circuit 740 are connected the output ports P5 to P8 of the identifier generation circuit 730 through TSVs 7305, respectively. Accordingly, the input signals of the first terminals of the logic gates 7401 to 7404 of the identifier generation circuit 740 will follow the input signals “0”, “1”, “1”, and “1” received at the input port P1 to P4 of the identifier generation circuit 740, respectively. Accordingly, the output signals “1”, “1”, “1”, and “1” generated by the logic gates 7401 to 7404 at the output ports P5 to P8 of the identifier generation circuit 740 will serve as the chip identifier ChipID4 (e.g., 4′b1111 or 0xF in hexadecimal).

It should be noted that the output signals of the identifier generation circuits 710, 720, 730, and 740 may be transmitted to the corresponding decoder circuits, such as the decoder circuits 212, 222, 232, and 242 shown in FIG. 2, allowing the logic circuitry disposed on different semiconductor dies to control the respective memory cell array (e.g., memory cell array 213, 223, 233, and 243 shown in FIG. 2) using the output signals from the identifier generation circuits 710, 720, 730, and 740.

FIG. 8 is a diagram illustrating operations of a stacked structure of identifier generation circuits in accordance with some embodiments of the present disclosure.

In some embodiments, the identifier generation circuits 810, 820, 830, and 840 within stacked structure 800 shown in FIG. 8 may correspond to the identifier generation circuits 214, 224, 234, and 244 disposed on semiconductor dies 210, 220, 230, and 240 shown in FIG. 2, respectively. In other words, the identifier generation circuits 810, 820, 830, and 840 are disposed on different semiconductor dies (not explicitly shown in FIG. 8). Additionally, the schematic diagrams of identifier generation circuit 810, 820, 830, and 840 with their respective input and output signals are shown in FIG. 8.

In some embodiments, the identifier generation circuit 810 may be disposed on a bottom semiconductor die among stacked structure 800. The input ports P1 to P3 of the identifier generation circuit 810 are connected to the ground voltage GND, while the input port P4 of the identifier generation circuit 810 is connected to the power supply voltage VDD, indicating that the input signal IN[3:0]=4′b0001 (e.g. 0x1 in hexadecimal). Additionally, since the second input terminal of the logic state 8104 is connected to the power supply voltage VDD through the resistor R1, the auxiliary input signal of the logic state 8104 is in the high logic state (e.g., “1”). Each of the logic gates 8101 to 8104 may perform a NOR operation on the corresponding bit and its adjacent lower bit of the input signal IN. For example, the logic gate 8101 may perform the NOR operation on the corresponding bit IN[3] received from the corresponding input port P1 and its adjacent lower bit IN[2] received from the adjacent input port P2. The operation for the logic gates 8102 to 8104 can be derived in a similar manner.

It should be noted that the auxiliary input signal serves as the adjacent lower bit for the logic state 8104. Accordingly, based on the truth table shown in Table 4, the output signals of the logic gates 8101 to 8104 are “1”, “1”, “0”, and “0”, that are transmitted to the output ports P5, P6, P7, and P8 of the identifier generation circuit 810, respectively. Accordingly, the output signals “1”, “1”, “0”, and “0” generated by the logic gates 8101 to 8104 at the output ports P5 to P8 of the identifier generation circuit 810 will serve as both the chip identifier ChipID1 (e.g., 4′b1100 or 0xC in hexadecimal) and the input signals at the input ports P1 to P4 of the identifier generation circuit 820.

Since the identifier generation circuit 820 is disposed on the second semiconductor die among stacked structure 800, the input ports P1 to P4 of the identifier generation circuit 820 are connected the output ports P5 to P8 of the identifier generation circuit 810 through TSVs 8105, respectively. Accordingly, the input signals of the first terminals of the logic gates 8201 to 8204 of the identifier generation circuit 820 will follow the input signals “1”, “1”, “0”, and “0” received at the input ports P1 to P4 of the identifier generation circuit 820, respectively. Accordingly, the output signals “0”, “0”, “1”, and “0” generated by the logic gates 8201 to 8204 at the output ports P5 to P8 of the identifier generation circuit 820 will serve as both the chip identifier ChipID2 (e.g., 4′b0010 or 0x2 in hexadecimal) and the input signals at the input ports P1 to P4 of the identifier generation circuit 830.

Similarly, since the identifier generation circuit 830 disposed on the third semiconductor die among stacked structure 800, the input ports P1 to P4 of the identifier generation circuit 830 are connected the output ports P5 to P8 of the identifier generation circuit 820 through TSVs 8205, respectively. Accordingly, the input signals of the first terminals of the logic gates 8301 to 8304 of the identifier generation circuit 830 will follow the input signals “0”, “0”, “1”, and “0” received at the input port P1 to P4 of the identifier generation circuit 830, respectively. Accordingly, the output signals “1”, “0”, “0”, and “0” generated by the logic gates 8301 to 8304 at the output ports P5 to P8 of the identifier generation circuit 830 will serve as both the chip identifier ChipID3 (e.g., 4′b1000 or 0x8 in hexadecimal) and the input signals at the input ports P1 to P4 of the identifier generation circuit 840.

Similarly, since the identifier generation circuit 840 is disposed on the fourth semiconductor die (or topmost semiconductor die) among stacked structure 800, the input ports P1 to P4 of the identifier generation circuit 840 are connected the output ports P5 to P8 of the identifier generation circuit 830 through TSVs 8305, respectively. Accordingly, the input signals of the first terminals of the logic gates 8401 to 8404 of the identifier generation circuit 840 will follow the input signals “1”, “0”, “0”, and “0” received at the input port P1 to P4 of the identifier generation circuit 840, respectively. Accordingly, the output signals “0”, “1”, “1”, and “0” generated by the logic gates 8401 to 8404 at the output ports P5 to P8 of the identifier generation circuit 840 will serve as the chip identifier ChipID4 (e.g., 4′b0110 or 0x6 in hexadecimal).

It should be noted that the output signals of the identifier generation circuits 810, 820, 830, and 840 may be transmitted to the corresponding decoder circuits, such as the decoder circuits 212, 222, 232, and 242 shown in FIG. 2, allowing the logic circuitry disposed on different semiconductor dies to control the respective memory cell array (e.g., memory cell array 213, 223, 233, and 243 shown in FIG. 2) using the output signals from the identifier generation circuits 810, 820, 830, and 840.

FIG. 9 is a diagram illustrating operations of a stacked structure of identifier generation circuits in accordance with some embodiments of the present disclosure.

In some embodiments, the identifier generation circuits 910, 920, 930, and 940 within stacked structure 900 shown in FIG. 9 may correspond to the identifier generation circuits 214, 224, 234, and 244 disposed on semiconductor dies 210, 220, 230, and 240 shown in FIG. 2, respectively. In other words, the identifier generation circuits 910, 920, 930, and 940 are disposed on different semiconductor dies (not explicitly shown in FIG. 9). Additionally, the schematic diagrams of identifier generation circuit 910, 920, 930, and 940 with their respective input and output signals are shown in FIG. 9.

In some embodiments, the identifier generation circuit 910 may be disposed on a bottom semiconductor die among stacked structure 900. The input ports P1 to P4 of the identifier generation circuit 910 are connected to the power supply voltage VDD, indicating that the input signal IN[3:0]=4′b1111 (e.g., 0xF in hexadecimal). Additionally, since the second input terminal of the logic state 9104 is connected to the power supply voltage VDD through the resistor R1, the auxiliary input signal of the logic state 9104 is in the high logic state (e.g., “1”). Each of the logic gates 9101 to 9104 may perform an XOR operation on the corresponding bit and its adjacent lower bit of the input signal IN. For example, the logic gate 9101 perform the XOR operation on the corresponding bit IN[3] received from the corresponding input port P1 and its adjacent lower bit IN[2] received from the adjacent input port P2. The operation for the logic gates 9102 to 9104 can be derived in a similar manner.

It should be noted that the auxiliary input signal serves as the adjacent lower bit for the logic state 9104. Accordingly, based on the truth table shown in Table 5, the output signals of the logic gates 9101 to 9104 are “0”, “0”, “0”, and “0”, that are transmitted to the output ports P5, P6, P7, and P8 of the identifier generation circuit 910, respectively. Accordingly, the output signals “0”, “0”, “0”, and “0” generated by the logic gates 9101 to 9104 at the output ports P5 to P8 of the identifier generation circuit 910 will serve as both the chip identifier ChipID1 (e.g., 4′b0000 or 0x0 in hexadecimal) and the input signals at the input ports P1 to P4 of the identifier generation circuit 920.

Since the identifier generation circuit 920 is disposed on the second semiconductor die among stacked structure 900, the input ports P1 to P4 of the identifier generation circuit 920 are connected the output ports P5 to P8 of the identifier generation circuit 910 through TSVs 9105, respectively. Accordingly, the input signals of the first terminals of the logic gates 9201 to 9204 of the identifier generation circuit 920 will follow the input signals “0”, “0”, “0”, and “0” received at the input ports P1 to P4 of the identifier generation circuit 920, respectively. Accordingly, the output signals “0”, “0”, “0”, and “1” generated by the logic gates 9201 to 9204 at the output ports P5 to P8 of the identifier generation circuit 920 will serve as both the chip identifier ChipID2 (e.g., 4′b0001 or 0x1 in hexadecimal) and the input signals at the input ports P1 to P4 of the identifier generation circuit 930.

Similarly, since the identifier generation circuit 930 disposed on the third semiconductor die among stacked structure 900, the input ports P1 to P4 of the identifier generation circuit 930 are connected the output ports P5 to P8 of the identifier generation circuit 920 through TSVs 9205, respectively. Accordingly, the input signals of the first terminals of the logic gates 9301 to 9304 of the identifier generation circuit 930 will follow the input signals “0”, “0”, “0”, and “1” received at the input port P1 to P4 of the identifier generation circuit 930, respectively. Accordingly, the output signals “0”, “0”, “1”, and “0” generated by the logic gates 9301 to 9304 at the output ports P5 to P8 of the identifier generation circuit 930 will serve as both the chip identifier ChipID3 (e.g., 4′b0010 or 0x2 in hexadecimal) and the input signals at the input ports P1 to P4 of the identifier generation circuit 940.

Similarly, since the identifier generation circuit 940 is disposed on the fourth semiconductor die (or topmost semiconductor die) among stacked structure 900, the input ports P1 to P4 of the identifier generation circuit 940 are connected the output ports P5 to P8 of the identifier generation circuit 930 through TSVs 9305, respectively. Accordingly, the input signals of the first terminals of the logic gates 9401 to 9404 of the identifier generation circuit 940 will follow the input signals “0”, “0”, “1”, and “0” received at the input port P1 to P4 of the identifier generation circuit 940, respectively. Accordingly, the output signals “0”, “1”, “1”, and “1” generated by the logic gates 9401 to 9404 at the output ports P5 to P8 of the identifier generation circuit 940 will serve as the chip identifier ChipID4 (e.g., 4′b0111 or 0x7 in hexadecimal).

It should be noted that the output signals of the identifier generation circuits 910, 920, 930, and 940 may be transmitted to the corresponding decoder circuits, such as the decoder circuits 212, 222, 232, and 242 shown in FIG. 2, allowing the logic circuitry disposed on different semiconductor dies to control the respective memory cell array (e.g., memory cell array 213, 223, 233, and 243 shown in FIG. 2) using the output signals from the identifier generation circuits 910, 920, 930, and 940.

FIG. 10 is a diagram illustrating operations of a stacked structure of identifier generation circuits in accordance with some embodiments of the present disclosure.

In some embodiments, the identifier generation circuits 1010, 1020, 1030, and 1040 within stacked structure 1000 shown in FIG. 10 may correspond to the identifier generation circuits 214, 224, 234, and 244 disposed on semiconductor dies 210, 220, 230, and 240 shown in FIG. 2, respectively. In other words, the identifier generation circuits 1010, 1020, 1030, and 1040 are disposed on different semiconductor dies (not explicitly shown in FIG. 10). Additionally, the schematic diagrams of identifier generation circuit 1010, 1020, 1030, and 1040 with their respective input and output signals are shown in FIG. 10.

In some embodiments, the identifier generation circuit 1010 may be disposed on a bottom semiconductor die among stacked structure 1000. The input ports P1 to P4 of the identifier generation circuit 1010 are connected to the ground voltage GND, indicating that the input signal IN[3:0]=4′b0000 (e.g. 0x0 in hexadecimal). Additionally, since the second input terminal of the logic state 1014 is connected to the power supply voltage VDD through the resistor R1, the auxiliary input signal of the logic state 1014 is in the high logic state (e.g., “1”). Each of the logic gates 1012 to 1014 may perform an XNOR operation on the corresponding bit and its adjacent lower bit of the input signal IN. For example, the logic gate 1011 perform the XNOR operation on the corresponding bit IN[3] received from the corresponding input port P1 and its adjacent lower bit IN[2] received from the adjacent input port P2. The operation for the logic gates 1012 to 1014 can be derived in a similar manner.

It should be noted that the auxiliary input signal serves as the adjacent lower bit for the logic state 1014. Accordingly, based on the truth table shown in Table 6, the output signals of the logic gates 1011 to 1014 are “1”, “1”, “1”, and “0”, that are transmitted to the output ports P5, P6, P7, and P8 of the identifier generation circuit 1010, respectively. Accordingly, the output signals “1”, “1”, “1”, and “0” generated by the logic gates 1011 to 1014 at the output ports P5 to P8 of the identifier generation circuit 1010 will serve as both the chip identifier ChipID1 (e.g., 4′b1110 or 0xE in hexadecimal) and the input signals at the input ports P1 to P4 of the identifier generation circuit 1020.

Since the identifier generation circuit 1020 is disposed on the second semiconductor die among stacked structure 1000, the input ports P1 to P4 of the identifier generation circuit 1020 are connected the output ports P5 to P8 of the identifier generation circuit 1010 through TSVs 1015, respectively. Accordingly, the input signals of the first terminals of the logic gates 1021 to 1024 of the identifier generation circuit 1020 will follow the input signals “1”, “1”, “1”, and “0” received at the input ports P1 to P4 of the identifier generation circuit 1020, respectively. Accordingly, the output signals “1”, “1”, “0”, and “1” generated by the logic gates 1021 to 1024 at the output ports P5 to P8 of the identifier generation circuit 1020 will serve as both the chip identifier ChipID2 (e.g., 4′b1100 or 0xC in hexadecimal) and the input signals at the input ports P1 to P4 of the identifier generation circuit 1030.

Similarly, since the identifier generation circuit 1030 disposed on the third semiconductor die among stacked structure 1000, the input ports P1 to P4 of the identifier generation circuit 1030 are connected the output ports P5 to P8 of the identifier generation circuit 1020 through TSVs 1025, respectively. Accordingly, the input signals of the first terminals of the logic gates 1031 to 1034 of the identifier generation circuit 1030 will follow the input signals “1”, “1”, “0”, and “0” received at the input port P1 to P4 of the identifier generation circuit 1030, respectively. Accordingly, the output signals “1”, “0”, “1”, and “0” generated by the logic gates 1031 to 1034 at the output ports P5 to P8 of the identifier generation circuit 1030 will serve as both the chip identifier ChipID3 (e.g., 4′b1010 or 0xA in hexadecimal) and the input signals at the input ports P1 to P4 of the identifier generation circuit 1040.

Similarly, since the identifier generation circuit 1040 is disposed on the fourth semiconductor die (or topmost semiconductor die) among stacked structure 1000, the input ports P1 to P4 of the identifier generation circuit 1040 are connected the output ports P5 to P8 of the identifier generation circuit 1030 through TSVs 1035, respectively. Accordingly, the input signals of the first terminals of the logic gates 1041 to 1044 of the identifier generation circuit 1040 will follow the input signals “1”, “0”, “1”, and “0” received at the input port P1 to P4 of the identifier generation circuit 1040, respectively. Accordingly, the output signals “0”, “0”, “0”, and “0” generated by the logic gates 1041 to 1044 at the output ports P5 to P8 of the identifier generation circuit 1040 will serve as the chip identifier ChipID4 (e.g., 4′b0000 or 0x0 in hexadecimal).

It should be noted that the output signals of the identifier generation circuits 1010, 1020, 1030, and 1040 may be transmitted to the corresponding decoder circuits, such as the decoder circuits 212, 222, 232, and 242 shown in FIG. 2, allowing the logic circuitry disposed on different semiconductor dies to control the respective memory cell array (e.g., memory cell array 213, 223, 233, and 243 shown in FIG. 2) using the output signals from the identifier generation circuits 1010, 1020, 1030, and 1040.

It should be noted that the preset value of the input signal IN[3:0] in the embodiments of FIGS. 5 to 10 are for purposes of description. With appropriate design of the preset value of the input signal IN[3:0], each of the identifier generation circuits within the stack structure can generate a unique identifier that represents the location of the respective identifier generation circuit within the stack structure. It should be noted that the chip identifier for each semiconductor die is not limited to 4 bits. When there are more semiconductor dies within the stack structure, the width of the identifier for each semiconductor die can be extended in a similar manner.

FIG. 11 is a flowchart of a method for automatically generating chip identifiers for semiconductor dies within a stacked structure in accordance with some embodiments of the present disclosure. Please refer to FIG. 2, FIG. 3, and FIG. 11.

In step 1110, a first semiconductor die (e.g., semiconductor die 210) and a second semiconductor die (e.g., semiconductor die 220) are obtained, wherein the first semiconductor die and the second semiconductor die comprise a first identifier generation circuit (e.g., identifier generation circuit 214) and a second identifier generation circuit (e.g., identifier generation circuit 224), respectively.

In step 1120, a stacked structure is formed by stacking the second semiconductor die on the first semiconductor die, wherein the first identifier generation circuit is electrically connected to the second identifier generation circuit.

In step 1130, a first chip identifier and a second chip identifier for the first semiconductor die and the second semiconductor die are generated by the first identifier generation circuit and the second identifier generation circuit, respectively, wherein the second chip identifier is generated using the first chip identifier and an auxiliary input signal. For example, the second identifier generation circuit may receive the first chip identifier generated by the first identifier generation circuit, and each logic gate within the second identifier generation circuit may perform a corresponding logical operation on the corresponding bit and its adjacent lower bit to generate a respective bit of the second chip identifier. For the logic gate corresponding to the least significant bit of the first chip identifier, the auxiliary input signal may serve as the adjacent lower bit of the least significant bit of the first chip identifier.

In an aspect of the present disclosure, a semiconductor device is provided, which includes a plurality of semiconductor dies arranged in a stacked structure. Each semiconductor die includes an identifier generation circuit electrically connected to the identifier generation circuits of other semiconductor dies. In response to a first semiconductor die not being a bottom semiconductor die within the stacked structure, a first identifier generation circuit of the first semiconductor die is configured to automatically generate a first chip identifier for the first semiconductor die based on an auxiliary input signal and a second chip identifier generated by a second identifier generation circuit of a second semiconductor die neighboring to and below the first semiconductor die

In some embodiments, the stacked structure is a three-dimensional stacked structure.

In some embodiments, a first input signal of the first identifier generation circuit of the first semiconductor die is the second chip identifier generated by the second identifier generation circuit.

In some embodiments, in response to the second semiconductor die being the bottom semiconductor die within the stacked structure, the second identifier generation circuit of the second semiconductor die is configured to automatically generate the second chip identifier for the second semiconductor die using the auxiliary input signal and a second input signal.

In some embodiments, the first chip identifier and the second chip identifier are different.

In some embodiments, the first identifier generation circuit comprises a plurality of first logic gates, a plurality of first input ports, and a plurality of first output ports, and the first logic gates correspond to the first input ports and the first output ports. Each first logic gate receives a corresponding bit and an adjacent lower bit thereof within the second chip identifier from the corresponding first input port.

In some embodiments, the first identifier generation circuit includes a plurality of first logic gates, a plurality of first input ports, and a plurality of first output ports. The first logic gates correspond to the first input ports and the first output ports. Each first logic gate receives a corresponding bit of the second chip identifier from the corresponding first input port.

In some embodiments, the auxiliary input signal serves as the adjacent lower bit for the first logic gate corresponding to a least significant bit of the first input signal.

In some embodiments, the first logic gates are two-input logic gates of the same type. The two-input logic gates are AND gates, NAND gates, OR gates, NOR gates, XOR gates, or XNOR gates.

In some embodiments, the second identifier generation circuit comprises a plurality of second logic gates, a plurality of second input ports, and a plurality of second output ports, and the second logic gates correspond to the second input ports and the second output ports. In response to the second semiconductor die being the bottom semiconductor die within the stacked structure, the plurality of second input ports of the second identifier generation circuit of the second semiconductor die receive the second input signal.

In some embodiments, a preset value of the second input signal is determined according to a type of the second logic gates.

In some embodiments, when a specific bit of the second input signal is 1, the second input port corresponding to the specific bit is provided with a power supply voltage; and when the specific bit of the second input signal is 0, the second input port corresponding to the specific bit is provided with a ground voltage.

In some embodiments, the first logic gates and the second logic gates are of the same type.

In some embodiments, the first identifier generation circuit is electrically connected to the second identifier generation circuit through a plurality of through-silicon vias within the second semiconductor die.

In some embodiments, the first chip identifier and the second chip identifier are transmitted to a first decoder circuit and a second decoder circuit disposed on the first semiconductor die and the second semiconductor die, respectively.

In another aspect of the present disclosure, a method for automatically generating chip identifier for semiconductor dies in a stacked structure is provided, which includes the following steps: obtaining a first semiconductor die and a second semiconductor die, wherein the first semiconductor die and the second semiconductor die comprise a first identifier generation circuit and a second identifier generation circuit, respectively; forming a stacked structure by stacking the second semiconductor die on the first semiconductor die, wherein the first identifier generation circuit is electrically connected to the second identifier generation circuit; and generating a first chip identifier and a second chip identifier for the first semiconductor die and the second semiconductor die by the first identifier generation circuit and the second identifier generation circuit, respectively, wherein the second chip identifier is generated using the first chip identifier and an auxiliary input signal.

In some embodiments, the method further includes the following step: electrically connecting the first identifier generation circuit to the second identifier generation circuit through a plurality of through-silicon vias within the first semiconductor die.

In some embodiments, the method further includes the following step: generating the first chip identifier using a preset value and the auxiliary input signal in response to the first semiconductor die being a bottom die within the stacked structure.

In some embodiments, the preset value corresponds to a type of a plurality of first logic gates within the first identifier generation circuit.

In some embodiments, the first logic gates are two-input logic gates of the same type. The two-input logic gates are AND gates, NAND gates, OR gates, NOR gates, XOR gates, or XNOR gates.

In some embodiments, the method further includes the following step: utilizing the first identifier generation circuit and the second identifier generation circuit to transmit the first chip identifier and the second chip identifier to a first decoder circuit and a second decoder circuit disposed on the first semiconductor die and the second semiconductor die, respectively.

In yet another aspect of the present disclosure, a memory device is provided, which includes a stacked structure having a first memory die and a second memory die. The first memory die is stacked on the second memory die. The first memory die and the second memory die include a first identifier generation circuit and a second identifier generation circuit, respectively. The second identifier generation circuit is configured to automatically generate a second chip identifier for the second memory die using a preset value and a first auxiliary input signal, and the first identifier generation circuit is configured to automatically generate a first chip identifier using the second chip identifier and a second auxiliary input signal.

In some embodiments, the first identifier generation circuit is electrically connected to the second identifier generation circuit through a plurality of through-silicon vias within the second memory die.

In some embodiments, the first auxiliary input signal is equal to the second auxiliary input signal.

In some embodiments, the first identifier generation circuit comprises a plurality of first logic gates, a plurality of first input ports, and a plurality of first output ports, and the first logic gates correspond to the first input ports and the first output ports. Each first logic gate receives a corresponding bit and an adjacent lower bit thereof within the second chip identifier from the corresponding first input port.

In some embodiments, the first auxiliary input signal serves as the adjacent lower bit for the first logic gate corresponding to a least significant bit of the second chip identifier.

In some embodiments, the second identifier generation circuit comprises a plurality of second logic gates, a plurality of second input ports, and a plurality of second output ports, and the second logic gates correspond to the second input ports and the second output ports. in response to the second memory die being a bottom semiconductor die within the stacked structure, the plurality of second input ports of the second identifier generation circuit of the second memory die receive the preset value.

In some embodiments, the first logic gates and the second logic gates are two-input logic gates of the same type.

In some embodiments, the two-input logic gates are AND gates, NAND gates, OR gates, NOR gates, XOR gates, or XNOR gates.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, or steps.

What is claimed is:

1. A method, comprising:
obtaining a first semiconductor die and a second semiconductor die, wherein the first semiconductor die and the second semiconductor die comprise a first identifier generation circuit and a second identifier generation circuit, respectively;
forming a stacked structure by stacking the second semiconductor die on the first semiconductor die, wherein the first identifier generation circuit is electrically connected to the second identifier generation circuit; and
generating a first chip identifier and a second chip identifier for the first semiconductor die and the second semiconductor die by the first identifier generation circuit and the second identifier generation circuit, respectively, wherein the second chip identifier is generated using the first chip identifier and an auxiliary input signal.

2. The method of claim 1, further comprising: electrically connecting the first identifier generation circuit to the second identifier generation circuit through a plurality of through-silicon vias within the first semiconductor die.

3. The method of claim 1, further comprising: generating the first chip identifier using a preset value and the auxiliary input signal in response to the first semiconductor die being a bottom die within the stacked structure.

4. The method of claim 3, wherein the preset value corresponds to a type of a plurality of first logic gates within the first identifier generation circuit.

5. The method of claim 4, wherein the first logic gates are two-input logic gates of the same type.

6. The method of claim 5, wherein the two-input logic gates are AND gates, NAND gates, OR gates, NOR gates, XOR gates, or XNOR gates.

7. The method of claim 1, further comprising: utilizing the first identifier generation circuit and the second identifier generation circuit to transmit the first chip identifier and the second chip identifier to a first decoder circuit and a second decoder circuit disposed on the first semiconductor die and the second semiconductor die, respectively.
